(19) United States
(12) Patent Application Publication
(10) Pub. No.: US 2026/0135025 A1
(43) Pub. Date: May 14, 2026

(54) SIGNAL TRANSMISSION ELEMENT

(71) Applicant: Mitsubishi Electric Corporation, Tokyo (JP)

(72) Inventors: Manabu YOSHINO, Tokyo (JP); Takuichiro SHITOMI, Tokyo (JP)

(73) Assignee: Mitsubishi Electric Corporation, Tokyo (JP)

(21) Appl. No.: 19/293,904

(22) Filed: Aug. 7, 2025

(30) Foreign Application Priority Data
Nov. 11, 2024 (JP) 2024-196521

(51) Int. Cl. H01F 17/00; H01F 27/29; H01F 27/32; H10D 86/80

(52) U.S. Cl. CPC H01F 17/0013; H01F 27/29; H10D 86/80; H01F 2017/0073; H01F 2017/008; H01F 2027/329

(57) ABSTRACT

A signal transmission element includes a first insulating layer on a semiconductor substrate, first and second coils thereon, a second insulating layer covering the first and second coils, third and fourth coils thereon, and a protective film covering the third and fourth coils. The first and third coils are magnetically coupled, the second and fourth coils are magnetically coupled, the first and second coils are connected to each other such that a current generated by mutual induction between the first coil and the third coil flows through the second coil, and the protective film includes a plurality of openings reaching two ends of the third coil and two ends of the fourth coil.

### BACKGROUND

### Technical Field

The present disclosure relates to a signal transmission element, and particularly to an isolated-type signal transmission element.

### Description of the Background Art

An isolated-type signal transmission element (transformer element) is an element that transmits a signal in a state where input and output are electrically and physically isolated. For example, in a gate driver of a power chip, a microcomputer for control is connected to an input side, and a gate of the power chip is connected to an output side, and a signal of the microcomputer is transmitted to the power chip. However, when a power chip to which a high voltage is applied has dielectric breakdown, the input side and the output side are electrically and physically isolated for safety of the system such as protection of the microcomputer and prevention of electric shock.

In an isolated-type signal transmission element that forms magnetic coupling in a direction perpendicular to a semiconductor substrate, in order to draw out an electrode of a lower layer coil close to the semiconductor substrate to an element surface, it is necessary to etch a thick insulating layer between the upper layer coil and the lower layer coil as illustrated in FIG. 21 of Japanese Patent Application Laid-Open No. 2023-124329, for example.

In Japanese Patent Application Laid-Open No. 2023-124329, it is necessary to etch a thick insulating layer between the upper layer coil and the lower layer coil in order to draw out the lower layer coil to the element surface, and there is a problem that the processing load of the wafer process increases.

### SUMMARY

An object of the present disclosure is to provide a signal transmission element that does not require a step of drawing out a lower layer coil to an element surface.

A signal transmission element according to the present disclosure includes: a first insulating layer provided on a semiconductor substrate; a first coil and a second coil provided adjacent to each other on the first insulating layer; a second insulating layer provided on the first insulating layer and covering the first and second coils; a third coil and a fourth coil provided adjacent to each other on the second insulating layer; and an insulating protective film provided on the second insulating layer and covering the third and fourth coils. The first coil and the third coil are magnetically coupled, the second coil and the fourth coil are magnetically coupled, and the first and second coils are connected to each other such that a current generated by mutual induction between the first coil and the third coil flows through the second coil, and the protective film has a plurality of openings reaching two ends of the third coil and two ends of the fourth coil.

According to the signal transmission element according to the present disclosure, since both the third coil on the input side and the fourth coil on the output side are provided on the second insulating layer, it is possible to obtain electrodes on the input side and the output side only by removing the protective film without removing the second insulating layer even if the thickness of the second insulating layer increases, so that it is possible to obtain a signal transmission element that does not require a step of drawing the lower layer coil to the element surface.

These and other objects, features, aspects and advantages of the present disclosure will become more apparent from the following detailed description of the present disclosure when taken in conjunction with the accompanying drawings.

### BRIEF DESCRIPTION OF THE DRAWINGS

FIG. 1 is a cross-sectional view illustrating a configuration of a signal transmission element according to a first preferred embodiment;

FIG. 2 is a plan view schematically illustrating a planar configuration of a metal wiring layer on a lower layer side of the signal transmission element according to the first preferred embodiment;

FIG. 3 is a plan view schematically illustrating a planar configuration of a metal wiring layer on an upper layer side of the signal transmission element according to the first preferred embodiment;

FIG. 4 is a plan view schematically illustrating a planar configuration of a modification of the metal wiring layer on the lower layer side of the signal transmission element according to the first preferred embodiment;

FIG. 5 is a cross-sectional view illustrating a configuration of a modification of the signal transmission element according to the first preferred embodiment;

FIG. 6 is a cross-sectional view illustrating a configuration of a signal transmission element according to a second preferred embodiment;

FIG. 7 is a plan view schematically illustrating a planar configuration of a metal wiring layer on a lower layer side of the signal transmission element according to the second preferred embodiment;

FIG. 8 is a plan view schematically illustrating a planar configuration of a metal wiring layer on an upper layer side of the signal transmission element according to the second preferred embodiment;

FIG. 9 is a plan view schematically illustrating a planar configuration of a metal wiring layer as an uppermost layer of the signal transmission element according to the second preferred embodiment;

FIG. 10 is a cross-sectional view illustrating a configuration of a modification of the signal transmission element according to the second preferred embodiment; and

FIG. 11 is a plan view schematically illustrating a planar configuration of a modification of the metal wiring layer on the upper layer side of the signal transmission element according to the second preferred embodiment.

### DESCRIPTION OF THE PREFERRED EMBODIMENTS

### First Preferred Embodiment

### <Device Configuration>

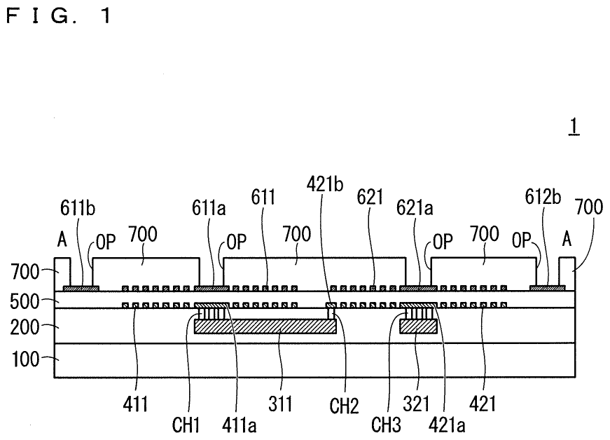

FIG. 1 is a cross-sectional view illustrating a configuration of a signal transmission element 1 according to a first preferred embodiment of the present disclosure. As illustrated in FIG. 1, in the signal transmission element 1, an insulating layer 200 (first insulating layer) is provided on a surface of a semiconductor substrate 100, and a metal wiring layer 311 and a metal wiring layer 321 are provided inside the insulating layer 200. Note that a silicon substrate or a silicon carbide substrate can be used as the semiconductor substrate 100, and an N-type or P-type impurity can be used. Further, a conductor or an insulator may be used as the substrate. Any of the metal wiring layers described below can be formed of metal such as copper or aluminum.

A metal wiring layer 411 (first coil) and a metal wiring layer 421 (second coil) are provided on the insulating layer 200, and the metal wiring layers 411 and 421 are covered with an insulating layer 500 (second insulating layer). The metal wiring layer 311 and a central portion end 411a of the metal wiring layer 411 are electrically connected via a contact hole CH1, and the metal wiring layer 311 and an outer peripheral portion end 421b of the metal wiring layer 421 are electrically connected via a contact hole CH2. The metal wiring layer 321 and a central portion end 421a of the metal wiring layer 421 are electrically connected via a contact hole CH3.

A metal wiring layer 611 (third coil) and a metal wiring layer 621 (fourth coil) are provided on the insulating layer 500, and the metal wiring layers 611 and 621 are covered with an insulating protective film 700 such as silicon nitride or silicon oxide, for example. Furthermore, the insulating layers 200 and 500 can be formed of, for example, silicon oxide.

The metal wiring layer 611 has ends 611a and 611b, the metal wiring layer 621 has ends 621a and 621b, and the protective film 700 is provided with a plurality of openings OP reaching the respective ends.

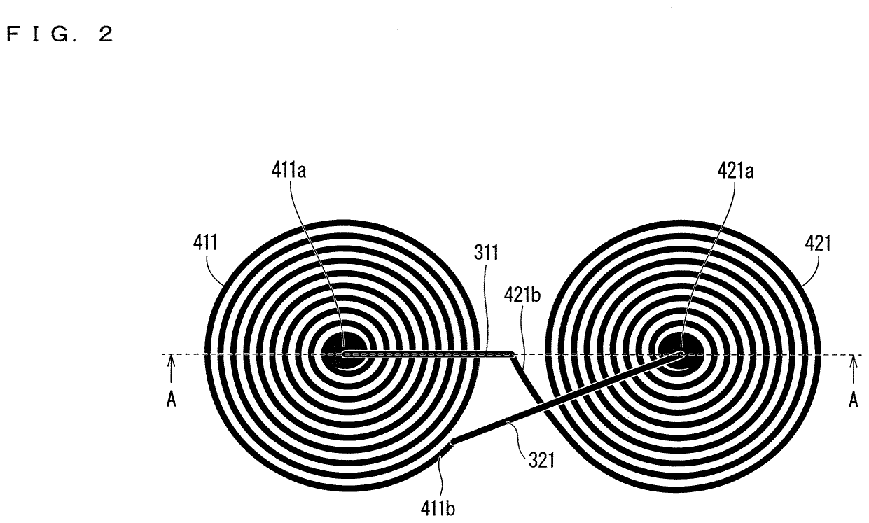

FIG. 2 is a plan view schematically illustrating a planar configuration of the metal wiring layers 311, 321, 411, and 421 on the lower layer side, and the metal wiring layers 311 and 321 to be the lower layers are illustrated to be superimposed on the metal wiring layers 411 and 421 for convenience. A cross section taken along line A-A in FIG. 2 in the direction of arrows is included in the cross-sectional view of FIG. 1.

The metal wiring layer 411 has a spiral shape in plan view, and has a spiral shape in a left winding direction from the central portion end 411a toward the outer peripheral portion end 411b in FIG. 2. The metal wiring layer 421 is disposed at a position away from the metal wiring layer 411 by a certain distance in plan view, and has a spiral shape opposite to that of the metal wiring layer 411. In FIG. 2, the metal wiring layer 421 has a spiral shape in a right winding direction from the central portion end 421a toward the outer peripheral portion end 421b.

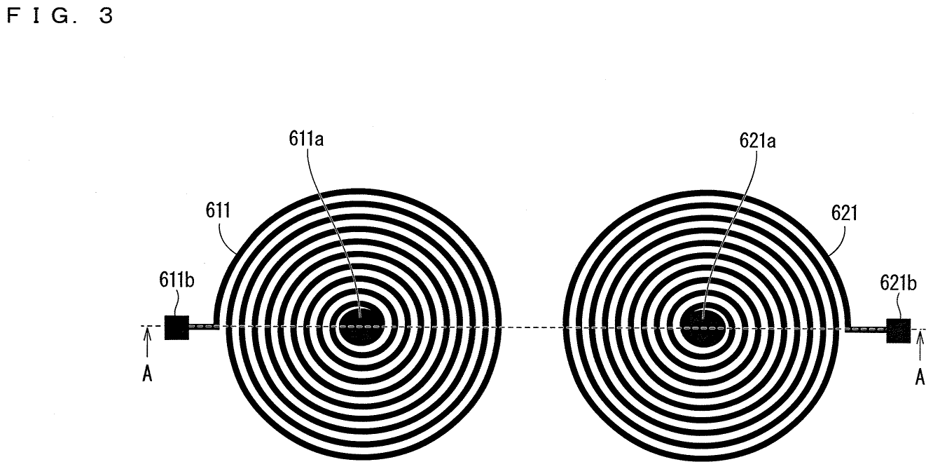

FIG. 3 is a plan view schematically illustrating a planar configuration of the metal wiring layers 611 and 621, and a cross section taken along line A-A in FIG. 3 in the direction of arrows is included in the cross-sectional view of FIG. 1.

The metal wiring layer 611 is provided above the metal wiring layer 411 with the insulating layer 500 interposed therebetween, has a spiral shape in plan view, and is magnetically coupled to the metal wiring layer 411. The metal wiring layer 621 is provided above the metal wiring layer 421 with the insulating layer 500 interposed therebetween, has a spiral shape in plan view, and is magnetically coupled to the metal wiring layer 421.

In FIG. 3, the spiral of the metal wiring layer 611 is in a left winding direction from the central portion end 611a toward the outer peripheral portion end 611b, and the spiral of the metal wiring layer 621 is in a right winding direction from the central portion end 621a toward the outer peripheral portion end 621b. However, the winding directions of the metal wiring layers 611 and 621 may be the same direction. In addition, the winding directions with respect to the lower metal wiring layers 411 and 421 may be the same or opposite.

### Operation and Effect

In the signal transmission element 1 of the first preferred embodiment, a current signal input between the central portion end 611a and the outer peripheral portion end 611b of the metal wiring layer 611 is output as a current signal between the central portion end 621a and the outer peripheral portion end 621b of the metal wiring layer 621. In FIG. 3, when a current is input from the central portion end 611a to the outer peripheral portion end 611b, a magnetic field is generated from the rear surface of the sheet toward the front surface of the sheet in the region of the metal wiring layer 611. An induced electromotive force is generated in the metal wiring layer 411 by mutual induction by the magnetic field, and a current flows from the central portion end 411a to the outer peripheral portion end 411b in FIG. 2. This current flows from the central portion end 421a of the metal wiring layer 421 to the outer peripheral portion end 421b via the metal wiring layers 321 and 311. When a current flows from the central portion end 421a to the outer peripheral portion end 421b, a magnetic field is generated in the region of the metal wiring layer 421 from the front surface of the sheet to the rear surface of the sheet. An induced electromotive force is generated in the metal wiring layer 621 by mutual induction by the magnetic field, and a current signal is output from the central portion end 621a to the outer peripheral portion end 621b in FIG. 3.

By the above operation, a current signal input between the central portion end 611a and the outer peripheral portion end 611b of the metal wiring layer 611 is output as a current signal between the central portion end 621a and the outer peripheral portion end 621b of the metal wiring layer 621.

Here, in FIG. 2, the magnetic field generated by the input current is directed from the rear surface of the sheet toward the front surface of the sheet in the region of the metal wiring layer 411, and is directed from the front surface of the sheet toward the rear surface of the sheet outside the region of the metal wiring layer 411, that is, in the region where the metal wiring layer 411 is not provided.

In addition, in FIG. 2, the magnetic field generated by the input current is directed from the front surface of the sheet toward the rear surface of the sheet in the region of the metal wiring layer 421, and is directed from the rear surface of the sheet toward the front surface of the sheet outside the region of the metal wiring layer 421, that is, in the region where the metal wiring layer 421 is not provided. Therefore, the magnetic field in the region of the metal wiring layer 421, which is a transmission signal, is strengthened without being offset by the magnetic field from the metal wiring layer 411, and a signal can be transmitted more efficiently.

In addition, as illustrated in FIG. 1, since the insulating layer 500 is interposed between the metal wiring layer 411 and the metal wiring layer 611 and between the metal wiring layer 421 and the metal wiring layer 621, the metal wiring layer 611 and the metal wiring layer 621 are electrically insulated while signal transmission is performed by mutual induction by the magnetic field.

Here, in the case of increasing the withstand voltage, it is necessary to increase the thickness of the insulating layer 500. However, in the signal transmission element 1 of the first preferred embodiment, since both the metal wiring layer 611 on the input side and the metal wiring layer 621 on the output side are provided on the insulating layer 500, electrodes on the input side and the output side can be obtained only by etching the protective film 700 without etching the insulating layer 500 even if the thickness of the insulating layer 500 increases.

### Modification 1

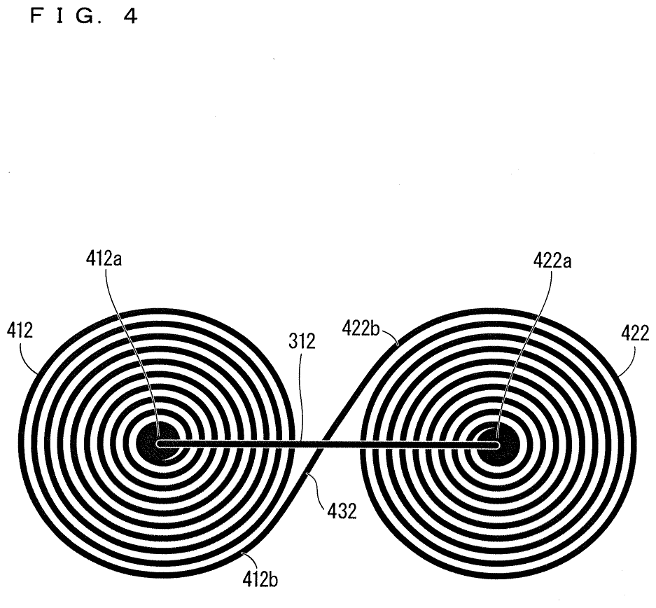

FIG. 4 is a plan view illustrating a modification of a combination of the winding directions of the spiral shapes of the metal wiring layers 411 and 421 illustrated in FIG. 2, which is different from the combination of the winding directions of the spiral shapes of the metal wiring layers 411 and 421 illustrated in FIG. 2.

That is, the spiral of the metal wiring layer 412 in FIG. 4 is in a left winding direction from the central portion end 412a toward the outer peripheral portion end 412b, and the winding direction of the spiral of the metal wiring layer 422 is in a left winding direction from the central portion end 422a toward the outer peripheral portion end 422b, which are in the same winding direction.

The central portion end 412a of the metal wiring layer 412 and the central portion end 422a of the metal wiring layer 422 are electrically connected by the metal wiring layer 312 via a contact hole (not illustrated) formed in the insulating layer 200 (FIG. 1).

The outer peripheral portion end 412b of the metal wiring layer 412 and the outer peripheral portion end 422b of the metal wiring layer 422 are connected by the metal wiring layer 432 that is the same layer on the insulating layer 200. Therefore, in FIG. 4, the boundaries between the outer peripheral portion end 412b, the metal wiring layer 432, and the outer peripheral portion end 422b are not illustrated.

Similarly to the metal wiring layers 411 and 421 illustrated in FIG. 2, in the metal wiring layers 412 and 422, when a current is input from the central portion end 611a to the outer peripheral portion end 611b in FIG. 3, a magnetic field is generated from the rear surface of the sheet toward the front surface of the sheet in the region of the metal wiring layer 611. An induced electromotive force is generated in the metal wiring layer 412 by mutual induction by the magnetic field, and a current flows from the central portion end 412a to the outer peripheral portion end 412b in FIG. 4. This current flows from the outer peripheral portion end 422b to the central portion end 422a of the metal wiring layer 422 via the metal wiring layers 432 and 312. When a current flows from the outer peripheral portion end 421b to the central portion end 422a, a magnetic field is generated in the region of the metal wiring layer 422 from the front surface to the rear surface of the sheet. An induced electromotive force is generated in the metal wiring layer 621 by mutual induction by the magnetic field, and a current signal is output from the central portion end 621a to the outer peripheral portion end 621b in FIG. 3.

By the above operation, a current signal input between the central portion end 611a and the outer peripheral portion end 611b of the metal wiring layer 611 is output as a current signal between the central portion end 621a and the outer peripheral portion end 621b of the metal wiring layer 621.

In addition, the magnetic field in the region of the metal wiring layer 422 serving as a transmission signal is strengthened without being offset by the magnetic field from the metal wiring layer 412, and a signal can be transmitted more efficiently.

### Modification 2

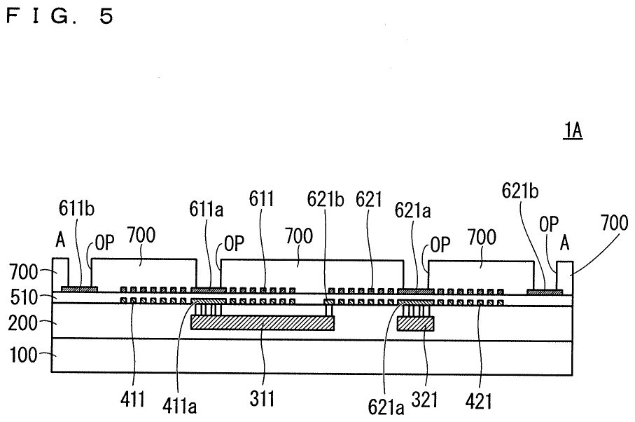

FIG. 5 is a cross-sectional view illustrating a configuration of a signal transmission element 1A in a case where the insulating layer 500 is thinned to form an insulating layer 510. Note that in FIG. 5, the same components as those of the signal transmission element 1 described with reference to FIG. 1 are denoted by the same reference numerals, and redundant description is omitted.

In the signal transmission element 1 of the first preferred embodiment, the input current signal is transmitted via the insulating layer 500 between the metal wiring layer 611 and the metal wiring layer 411, and is transmitted via the insulating layer 500 between the metal wiring layer 421 and the metal wiring layer 621, and thus is transmitted via the insulating layer 500 twice. Therefore, the insulating layer 500 can be thinned.

That is, when the thickness of the insulating layer 500 satisfying the required withstand voltage between the metal wiring layers 411 and 421 and the metal wiring layers 611 and 621 is, for example, L, the input current signal is transmitted through the insulating layer 500 twice, so that a thickness L1 of the insulating layer 510 can be set to L/2≤L1<L, that is, half the thickness of the insulating layer 500. Therefore, the processing load on the insulating layer 510 can be reduced.

### Second Preferred Embodiment

In the first preferred embodiment described with reference to FIGS. 1 to 4, the number of adjacent spiral metal wiring layers in the same layer is two, that is, the metal wiring layers 411 and 421 in FIG. 2, but a configuration in which a plurality of blocks of this combination is connected can also be adopted.

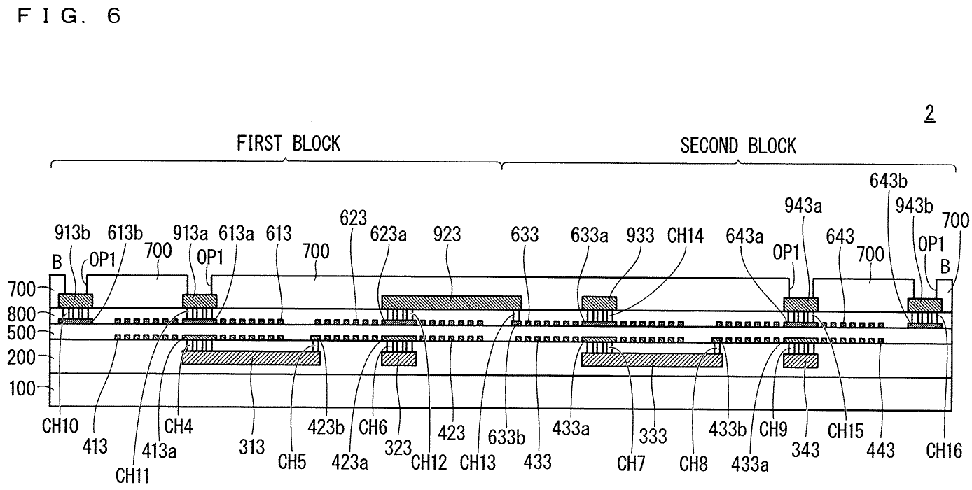

Hereinafter, as a second preferred embodiment according to the present disclosure, a configuration in which two blocks of the configuration of the first preferred embodiment are connected will be described with reference to FIGS. 6 to 8.

FIG. 6 is a cross-sectional view illustrating a configuration of a signal transmission element 2 according to the second preferred embodiment of the present disclosure. As illustrated in FIG. 6, in the signal transmission element 2, an insulating layer 200 is provided on a surface of a semiconductor substrate 100, and metal wiring layers 313, 323, 333, and 343 are provided inside the insulating layer 200.

Metal wiring layers 413, 423, 433, and 443 are provided on the insulating layer 200, and the metal wiring layers 413, 423, 433, and 443 are covered with an insulating layer 500. The metal wiring layer 313 and a central portion end 413a of the metal wiring layer 413 are electrically connected via a contact hole CH4, and the metal wiring layer 313 and an outer peripheral portion end 423b of the metal wiring layer 423 are electrically connected via a contact hole CH5. The metal wiring layer 323 and the central portion end 423a of the metal wiring layer 423 are electrically connected via a contact hole CH6.

The metal wiring layer 333 and a central portion end 433a of the metal wiring layer 433 are electrically connected via a contact hole CH7, and the metal wiring layer 333 and an outer peripheral portion end 443b of the metal wiring layer 443 are electrically connected via a contact hole CH8. The metal wiring layer 343 and the central portion end 443a of the metal wiring layer 443 are electrically connected via a contact hole CH9.

Metal wiring layers 613, 623, 633, and 643 are provided on the insulating layer 500, and the metal wiring layers 613, 623, 633, and 643 are covered with an insulating layer 800 (third insulating layer). The insulating layer 800 can be formed of, for example, silicon oxide.

Metal wiring layers 913b, 913a, 923, 933, 943a, and 943b are provided on the insulating layer 800. The metal wiring layers 913b, 913a, 923, 933, 943a, and 943b are covered with an insulating protective film 700. The protective film 700 is provided with a plurality of openings OP1 reaching the metal wiring layers 913b, 913a, 943a, and 943b, respectively.

An outer peripheral portion end 613b of the metal wiring layer 613 and the metal wiring layer 913b are electrically connected via a contact hole CH10, and a central portion end 613a of the metal wiring layer 613 and the metal wiring layer 913a are electrically connected via a contact hole CH11. A central portion end 623a of the metal wiring layer 623 and the metal wiring layer 923 are electrically connected via a contact hole CH12, and an outer peripheral portion end 633b of the metal wiring layer 633 and the metal wiring layer 923 are electrically connected via a contact hole CH13. A central portion end 633a of the metal wiring layer 633 and the metal wiring layer 933 are electrically connected via a contact hole CH14. A central portion end 643a of the metal wiring layer 643 and the metal wiring layer 943a are electrically connected via a contact hole CH15, and an outer peripheral portion end 643b of the metal wiring layer 643 and the metal wiring layer 943b are electrically connected via a contact hole CH16.

In the signal transmission element 2 of the second embodiment, a current signal input between the metal wiring layer 913a and the metal wiring layer 913b is output between the metal wiring layer 943a and the metal wiring layer 943b.

In the signal transmission element 2 illustrated in FIG. 6, a portion on the left side in the drawing including the metal wiring layers 313 and 323 and the metal wiring layers 613 and 623 is referred to as a first block, and a portion on the right side in the drawing including the metal wiring layers 333 and 343 and the metal wiring layers 633 and 643 is referred to as a second block.

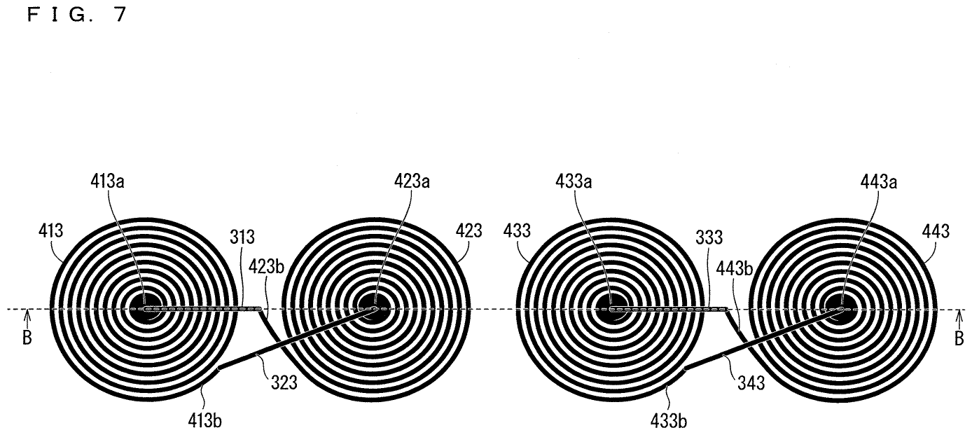

FIG. 7 is a plan view schematically illustrating a planar configuration of the metal wiring layers 413, 423, 433, and 443, in which the metal wiring layers 313 and 323 as lower layers are illustrated while superimposed on the metal wiring layers 413 and 423 for convenience, and the metal wiring layers 333 and 343 as lower layers are illustrated while superimposed on the metal wiring layers 433 and 443 for convenience. Note that a cross section taken along line B-B in FIG. 7 in the direction of arrows is included in the cross-sectional view of FIG. 6.

The plan view shapes of the metal wiring layers 413 and 423 and the plan view shapes of the metal wiring layers 433 and 443 are the same as the plan view shapes of the metal wiring layers 411 and 421 illustrated in FIG. 2.

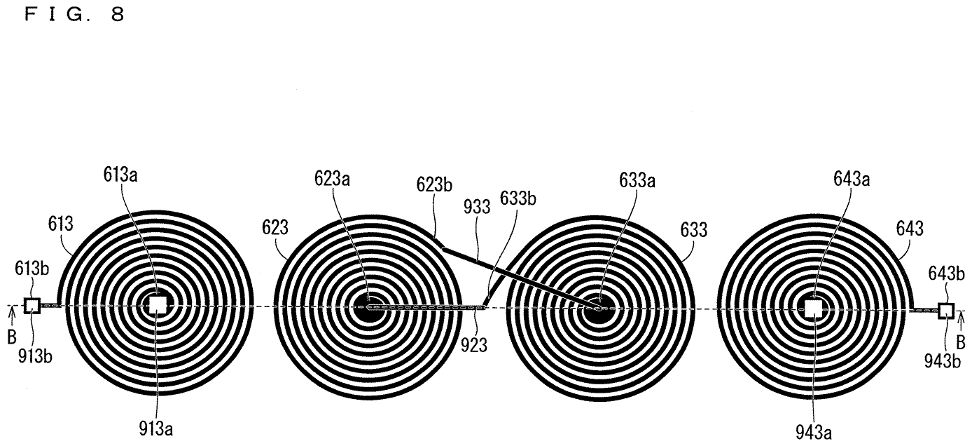

FIG. 8 is a plan view schematically illustrating a planar configuration of the metal wiring layers 613, 623, 633, and 643, and also illustrates the metal wiring layers 913b, 913a, 923, 933, 943a, and 943b as upper layers. A cross section taken along line B-B in FIG. 8 in the direction of arrows is included in the cross-sectional view of FIG. 6.

The plan view shapes of the metal wiring layers 613 and 623 and the plan view shapes of the metal wiring layers 633 and 643 are the same as the plan view shapes of the metal wiring layers 611 and 621 illustrated in FIG. 3, but the central portion end 623a of the metal wiring layer 623 and the outer peripheral portion end 633b of the metal wiring layer 633 are electrically connected by the metal wiring layer 923. In addition, the central portion end 633a of the metal wiring layer 633 and the outer peripheral portion end 623b of the metal wiring layer 623 are electrically connected by the metal wiring layer 933.

In FIG. 8, the metal wiring layers 913b, 913a, 943a, and 943b are smaller than the metal wiring layers 613b, 613a, 643a, and 643b in plan view, and are formed such that the outlines thereof are inside the outlines of the metal wiring layers 613b, 613a, 643a, and 643b, but the present invention is not limited thereto.

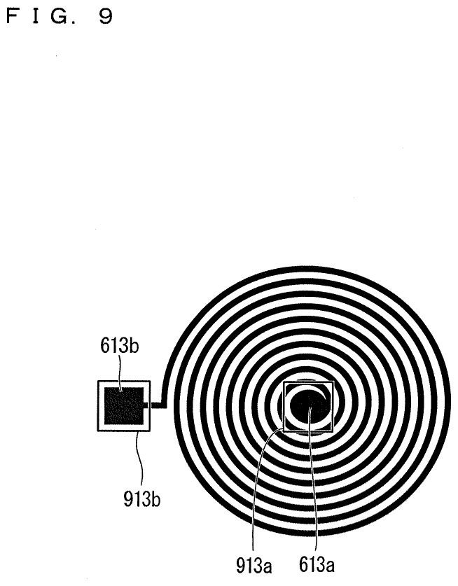

For example, as illustrated in FIG. 9, the metal wiring layers 913b and 913a are larger than the metal wiring layers 613b and 613a, and are formed such that the outlines thereof are outside the outlines of the metal wiring layers 613b and 613a.

There is no particular limitation on the magnitude relationship between the metal wiring layer 613b and the metal wiring layer 913b, and between the metal wiring layer 613a and the metal wiring layer 913a. The same applies to the metal wiring layer 643b and the metal wiring layer 943b, and the metal wiring layer 643a and the metal wiring layer 943a.

### Effects

As in the signal transmission element 1 of the first preferred embodiment, the signal transmission element 2 of the second preferred embodiment described above has an effect that electrodes on the input side and the output side can be obtained only by etching the protective film 700 without etching the insulating layer 500 even when the thickness of the insulating layer 500 increases.

In addition, by connecting a plurality of blocks of the configuration of the first preferred embodiment, a signal is transmitted through the insulating layer 500 twice or more while the signal is transmitted between the blocks, and the withstand voltage between the input and the output can be increased without increasing the thickness of the insulating layer 500.

That is, in the signal transmission element 1 of the first preferred embodiment, a current signal input to the outer peripheral portion end 611b of the metal wiring layer 611 is transmitted via the insulating layer 500 between the metal wiring layer 611 and the metal wiring layer 411, and is transmitted via the insulating layer 500 between the metal wiring layer 421 and the metal wiring layer 621, so that the current signal is transmitted via the insulating layer 500 twice.

On the other hand, in the signal transmission element 2 of the second preferred embodiment, a current signal input to the metal wiring layer 613b is transmitted via the insulating layer 500 between the metal wiring layer 613 and the metal wiring layer 413, transmitted via the insulating layer 500 between the metal wiring layer 423 and the metal wiring layer 623, transmitted via the insulating layer 500 between the metal wiring layer 633 and the metal wiring layer 433, and transmitted via the insulating layer 500 between the metal wiring layer 443 and the metal wiring layer 643, so that the current signal is transmitted via the insulating layer 500 four times, and the withstand voltage can be increased.

### Modification 1

Although the signal transmission element 2 of the second preferred embodiment illustrated in FIG. 6 is formed using the semiconductor substrate 100 as a substrate, a Silicon On Insulator (SOI) substrate can also be used as the substrate.

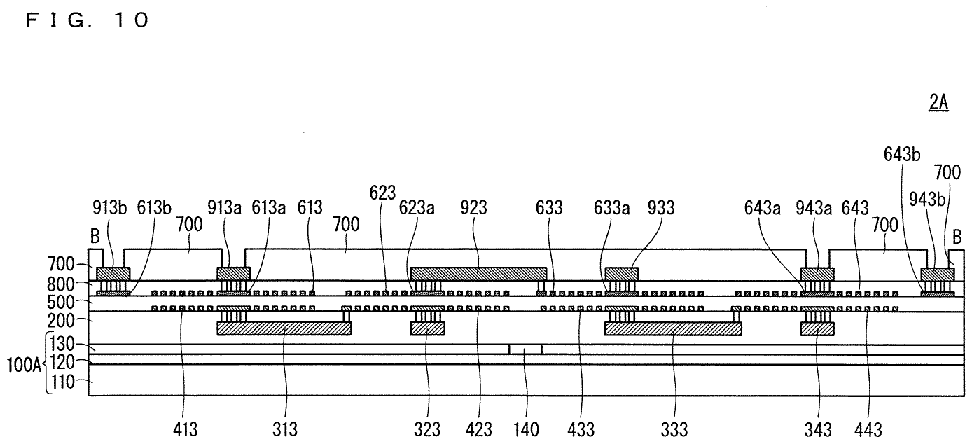

FIG. 10 is a cross-sectional view illustrating a configuration of a signal transmission element 2A using the SOI substrate 100A. Note that in FIG. 10, the same components as those of the signal transmission element 2 described with reference to FIG. 6 are denoted by the same reference numerals, and duplicate description will be omitted.

As illustrated in FIG. 10, in the signal transmission element 2A, each layer above the insulating layer 200 is provided on the SOI substrate 100A. The SOI substrate 100A has a configuration in which an embedded insulating layer 120 made of silicon oxide is provided on a semiconductor substrate 110, a semiconductor layer 130 made of single crystal silicon is provided on the embedded insulating layer 120, and an insulating layer 200 is provided on the semiconductor layer 130. Note that a silicon substrate can be used as the semiconductor substrate 110, and an N-type or P-type impurity can be used.

The embedded insulating layer 120 is, for example, a thermal oxide film. Note that the conductivity types of the semiconductor substrate 110 and the semiconductor layer 130 may be N type or P type.

In the semiconductor layer 130, a separation insulating layer 140 is formed between the metal wiring layer 423 and the metal wiring layer 433 when viewed from above, and is electrically separated.

An upper end of the separation insulating layer 140 is in contact with the insulating layer 200, and a lower end of the separation insulating layer 140 is in contact with the embedded insulating layer 120. The separation insulating layer 140 can be formed by thermal oxidation of the semiconductor layer 130, or can be formed by embedding the insulating layer after etching the semiconductor layer 130.

By using the SOI substrate 100A and providing the separation insulating layer 140, dielectric breakdown between the metal wiring layers 413 and 423 and the metal wiring layers 433 and 443 via the substrate can be suppressed, and the withstand voltage between the input and the output can be increased without increasing the thickness of the insulating layer 200.

### Modification 2

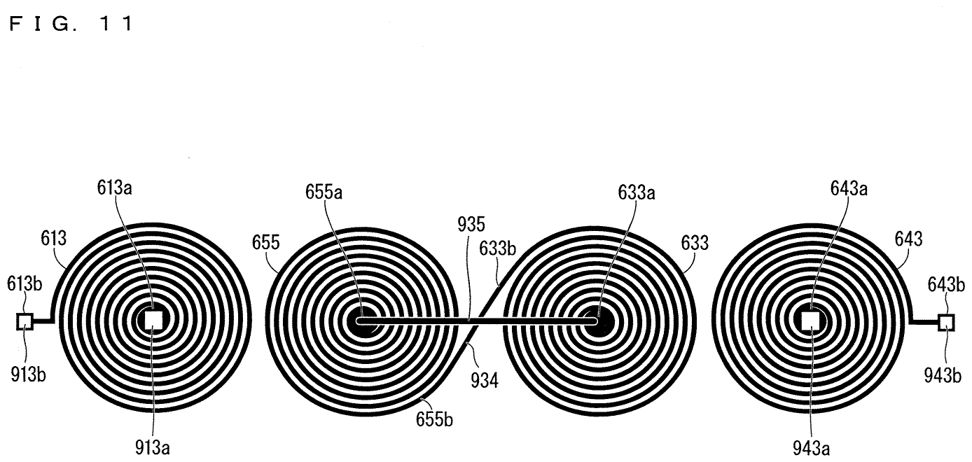

FIG. 11 is a plan view illustrating a modification of a combination of the winding directions of the spiral shapes of the metal wiring layers 623 and 633 illustrated in FIG. 8, which is different from the combination of the winding directions of the spiral shapes of the metal wiring layers 623 and 633 illustrated in FIG. 8.

That is, the spiral of a metal wiring layer 655 in FIG. 11 is in a left winding direction from a central portion end 655a toward an outer peripheral portion end 655b, and the winding direction of the spiral of the metal wiring layer 633 is in a left winding direction from the central portion end 633a toward the outer peripheral portion end 633b, which are in the same winding direction.

The central portion end 655a of the metal wiring layer 655 and the central portion end 633a of the metal wiring layer 633 are electrically connected by a metal wiring layer 935 via a contact hole (not illustrated) formed in the insulating layer 800 (FIG. 6).

The outer peripheral portion end 655b of the metal wiring layer 655 and the outer peripheral portion end 633b of the metal wiring layer 633 are connected by a metal wiring layer 934 that is the same layer on the insulating layer 500. Therefore, in FIG. 11, the boundaries between the outer peripheral portion end 655b, the metal wiring layer 934, and the outer peripheral portion end 633b are not illustrated.

In the present disclosure, the respective preferred embodiments can be freely combined or appropriately modified or omitted within the scope of the present disclosure.

The present disclosure described above will be collectively described as appendices.

### APPENDIX 1

A signal transmission element comprising:
a first insulating layer provided on a semiconductor substrate;
a first coil and a second coil provided adjacent to each other on the first insulating layer;
a second insulating layer provided on the first insulating layer and covering the first coil and the second coil, and a third coil and a fourth coil provided adjacent to each other on the second insulating layer; and
a protective film having an insulating property, the protective film being provided on the second insulating layer and covering the third coil and the fourth coil, wherein
the first coil and the third coil are magnetically coupled,
the second coil and the fourth coil are magnetically coupled,
the first coil and second coil are connected to each other such that a current generated by mutual induction between the first coil and the third coil flows through the second coil, and
the protective film includes a plurality of openings reaching two ends of the third coil and two ends of the fourth coil.

### APPENDIX 2

The signal transmission element according to Appendix 1, wherein
the first coil and the second coil are wound in opposite directions, and a central portion end of the first coil and an outer peripheral portion end of the second coil are electrically connected to each other, and
an outer peripheral portion end of the first coil and a central portion end of the second coil are electrically connected to each other.

### APPENDIX 3

The signal transmission element according to Appendix 1, wherein
the first coil and the second coil are wound in a same direction, and a central portion end of the first coil and a central portion end of the second coil are electrically connected to each other, and
an outer peripheral portion end of the first coil and an outer peripheral portion end of the second coil are electrically connected to each other.

### APPENDIX 4

The signal transmission element according to any one of Appendices 1 to 3, wherein a thickness of the second insulating layer is

set to half of a thickness required for withstand voltage between the first coil and the second coil, and the third coil and the fourth coil.

### APPENDIX 5

A signal transmission element comprising:
a first insulating layer provided on a semiconductor substrate;
a first coil and a second coil provided adjacent to each other on the first insulating layer;
a second insulating layer provided on the first insulating layer and covering the first coil and the second coil, and a third coil and a fourth coil provided adjacent to each other on the second insulating layer;
a third insulating layer provided on the second insulating layer and covering the third coil and the fourth coil, and a plurality of wiring layers provided on the third insulating layer;
a protective film having an insulating property, the protective film being provided on the third insulating layer and covering the plurality of wiring layers, wherein
the first coil and the third coil are magnetically coupled,
the second coil and the fourth coil are magnetically coupled,
the signal transmission element includes:
   a first block in which the first coil and the second coil are connected to each other such that a current generated by mutual induction between the first coil and the third coil flows through the second coil; and
   a second block having a same configuration as the first block,
the first block and the second block are provided so as to be continuous in plan view,
the fourth coil in the first block and the third coil in the second block are connected to each other such that a current flowing through the fourth coil in the first block flows through the third coil in the second block, and
the protective film includes a plurality of openings reaching two ends of the third coil in the first block and two ends of the fourth coil in the second block.

### APPENDIX 6

The signal transmission element according to Appendix 5, wherein
the fourth coil in the first block and the third coil in the second block are wound in opposite directions, and a central portion end of the fourth coil of the first block and an outer peripheral portion end of the third coil of the second block are electrically connected to each other, and
an outer peripheral portion end of the fourth coil in the first block and a central portion end of the third coil in the second block are electrically connected to each other.

### APPENDIX 7

The signal transmission element according to Appendix 5, wherein
the semiconductor substrate is an SOI substrate including:
   a silicon substrate;
   an embedded insulating layer provided on the silicon substrate; and
   a semiconductor layer provided on the embedded insulating layer, and the semiconductor layer includes
a separation insulating layer provided in a portion corresponding to a portion between the first block and the second block in plan view so as to reach the embedded insulating layer.

### APPENDIX 8

The signal transmission element according to Appendix 5, wherein
the fourth coil in the first block and the third coil in the second block are wound in a same direction, and a central portion end of the fourth coil in the first block and a central portion end of the third coil in the second block are connected to each other, and
an outer peripheral portion end of the fourth coil in the first block and an outer peripheral portion end of the third coil in the second block are connected to each other.

While the disclosure has been shown and described in detail, the foregoing description is in all aspects illustrative and not restrictive. It is therefore understood that numerous modifications and variations can be devised.

What is claimed is:

1. A signal transmission element comprising:
a first insulating layer provided on a semiconductor substrate;
a first coil and a second coil provided adjacent to each other on the first insulating layer;
a second insulating layer provided on the first insulating layer and covering the first coil and the second coil;
a third coil and a fourth coil provided adjacent to each other on the second insulating layer; and
a protective film having an insulating property, the protective film being provided on the second insulating layer and covering the third coil and the fourth coil,
wherein the first coil and the third coil are magnetically coupled,
the second coil and the fourth coil are magnetically coupled,
the first coil and second coil are connected to each other such that a current generated by mutual induction between the first coil and the third coil flows through the second coil, and
the protective film includes a plurality of openings reaching two ends of the third coil and two ends of the fourth coil.

2. The signal transmission element according to claim 1, wherein
the first coil and the second coil are wound in opposite directions, and a central portion end of the first coil and an outer peripheral portion end of the second coil are electrically connected to each other, and
an outer peripheral portion end of the first coil and a central portion end of the second coil are electrically connected to each other.

3. The signal transmission element according to claim 1, wherein
the first coil and the second coil are wound in a same direction, and a central portion end of the first coil and a central portion end of the second coil are electrically connected to each other, and
an outer peripheral portion end of the first coil and an outer peripheral portion end of the second coil are electrically connected to each other.

4. The signal transmission element according to claim 1, wherein a thickness of the second insulating layer is set to half of a thickness required for withstand voltage between the first coil and the second coil, and the third coil and the fourth coil.

5. A signal transmission element comprising:
a first insulating layer provided on a semiconductor substrate;
a first coil and a second coil provided adjacent to each other on the first insulating layer;
a second insulating layer provided on the first insulating layer and covering the first coil and the second coil;
a third coil and a fourth coil provided adjacent to each other on the second insulating layer;
a third insulating layer provided on the second insulating layer and covering the third coil and the fourth coil;
a plurality of wiring layers provided on the third insulating layer; and
a protective film having an insulating property, the protective film being provided on the third insulating layer and covering the plurality of wiring layers,
wherein the first coil and the third coil are magnetically coupled,
the second coil and the fourth coil are magnetically coupled,
the signal transmission element includes:
a first block in which the first coil and the second coil are connected to each other such that a current generated by mutual induction between the first coil and the third coil flows through the second coil; and
a second block having a same configuration as the first block,
the first block and the second block are provided so as to be continuous in plan view,
the fourth coil in the first block and the third coil in the second block are connected to each other such that a current flowing through the fourth coil in the first block flows through the third coil in the second block, and
the protective film includes a plurality of openings reaching two ends of the third coil in the first block and two ends of the fourth coil in the second block.

6. The signal transmission element according to claim 5, wherein
the fourth coil in the first block and the third coil in the second block are wound in opposite directions, and a central portion end of the fourth coil in the first block and an outer peripheral portion end of the third coil in the second block are electrically connected to each other, and
an outer peripheral portion end of the fourth coil in the first block and a central portion end of the third coil in the second block are electrically connected to each other.

7. The signal transmission element according to claim 5, wherein
the semiconductor substrate is an SOI substrate including:
a silicon substrate;
an embedded insulating layer provided on the silicon substrate; and
a semiconductor layer provided on the embedded insulating layer, and
the semiconductor layer includes a separation insulating layer provided in a portion corresponding to a portion between the first block and the second block in plan view so as to reach the embedded insulating layer.

8. The signal transmission element according to claim 5, wherein
the fourth coil in the first block and the third coil in the second block are wound in a same direction, and a central portion end of the fourth coil in the first block and a central portion end of the third coil in the second block are connected to each other, and
an outer peripheral portion end of the fourth coil in the first block and an outer peripheral portion end of the third coil in the second block are electrically connected to each other.
